(19) United States
(12) Patent Application Publication
(10) Pub. No.: US 2007/0019391 A1
(43) Pub. Date: Jan. 25, 2007

(54) Techniques for cooling electronic equipment

(75) Inventors: Guoping Xu, San Diego, CA (US); Gary L. Gilbert, San Diego, CA (US); Nicholas E. Aneshansley, San Diego, CA (US)

Correspondence Address: OSHA LIANG L.L.P./SUN, 1221 MCKINNEY, SUITE 2800, HOUSTON, TX, 77010, US

(73) Assignee: Sun Microsystems, Inc., Santa Clara, CA (US)

(21) Appl. No.: 11/185,531

(22) Filed: Jul. 20, 2005

(51) Int. Cl. H05K 5/00

(52) U.S. Cl. 361/752

(57) ABSTRACT

Electronic equipment housed in a cabinet is cooled using air that flows from one of a right side and a left side of the electronic equipment to the other one of the right side and the left side of the electronic equipment. The air is cooled using a heat exchanger that uses water or a refrigerant supplied to the cabinet. One or more components of the electronic equipment may be accessed via a front or back door of the cabinet without disrupting the cooling air flow in other components of the electronic equipment.

### BACKGROUND

A computer system frequently needs data and/or services from another computer system. For example, a bank customer may request to see his current bank account information on his home computer system, which obtains the requested information from a computer system maintained by and located at the bank. In such arrangements, the computer system requesting the data and/or service is referred to and known as the “client” system, and the computer system servicing the request is referred to and known as the “server” system.

Many entities, for various reasons, situate groups of servers and related electronic equipment in “server rooms” or “data centers.” Within a server room, several servers may be positioned vertically atop one another (with spacing) using a “rack.” Racks of servers (hereinafter generally referred to as “electronic equipment”) are often housed or enclosed in “cabinets” that provide protection from environmental variables such as, for example, light and dust. Cabinets may have front and back doors so as to allow for the servicing and changing of cabinet components. Moreover, cabinets reduce or prevent electromagnetic interference that might otherwise exist between, for example, different servers.

An important issue regarding server rooms involves temperature. As those skilled in the art will note, computer operation results in heat dissipation. In a server room, thousands of processors may be operating at the same time, and thus, without an adequate cooling technique, the servers and related electronic equipment in the server room may be damaged or operate incorrectly as a result of high temperatures.

One cooling technique cools servers and related electronic equipment using air supplied from within the server room. FIG. 1 shows such a server room 10. The server room 10 has two cabinets 12, 14, each of which houses servers and/or related electronic equipment (not shown). Cold air is introduced into the server room 10 using a plenum 16 of cold air supplied by an air conditioning unit (not shown). The cold air from the plenum 16 is directed to the front of each cabinet 12, 14. Cold air entering the front of each cabinet 12, 14 flows through the cabinets 12, 14 and is heated by the heat dissipation of the electronic equipment housed in the cabinets 12, 14. Consequently, hot air exits from the rear of each cabinet 12, 14 and returns to the server room 10. The hot air rises and enters a cooling coil 18, which uses water or a refrigerant supplied by a chiller unit 20 to cool the hot air and return cold air back to the server room 10. This returned cold air is directed to the front of each cabinet 12, 14.

As servers and related electronic equipment become more powerful, heat dissipation increases. In other words, as servers and related electronic equipment continue to improve in terms of density, computing speed, and performance, more energy is released, thereby resulting in increased heat dissipation. Using only an air cooling technique to cool a server room having such increased heat dissipation requires the consideration of some potentially problematic issues. For example, air cooling such a server room might require an air plenum below the floor of the server room that is significantly wider than one used for a server room not having increased heat dissipation. Further, the mixing of cold air and hot air in the server room might be of more significant concern than in a server room not having increased heat dissipation. Further, the increased volume of air flow that would be required to cool the server room might render the server room uncomfortable for operators and technicians in the server room.

A technique that may be used to somewhat address the concerns associated with using only air cooling to cool high heat dissipation server rooms involves the use of a liquid coolant. Liquid cooling may be used in combination with a front-to-back air cooling technique, such as that described above with reference to FIG. 1. FIG. 2 shows such a technique. Particularly, FIG. 2 shows a side view of a cabinet 32. An air-liquid heat exchanger 30 is placed at the bottom of the cabinet 32 underneath electronic equipment (e.g., servers) 34. The hot air exiting from the rear of the electronic equipment is captured by a back door 36 of the cabinet 32 with fans (not shown) and is directed down along the back door 36 to the air-liquid heat exchanger 30. The air-liquid heat exchanger 30 cools the hot air, and the resulting cold air is directed up the front of the cabinet 32 between a front door 38 of the cabinet 32 and the electronic equipment 34 to be cooled. The air re-circulates within the cabinet 32 as the front door 38 and back door 36 of the cabinet 32 are closed. Those skilled in the art will note that the front and rear surfaces of the electronic equipment 34 represent space for connectors for the electronic equipment 34, and thus, front-to-back air cooling may limit such use of the front and rear surfaces of the electronic equipment 34.

Further, those skilled in the art will note that servicing a component in such front-to-back air cooled electronic equipment may result in a disruption to the air flow within the cabinet, thereby requiring an adequate air cooling technique within the server room so as to keep the other components of the electronic equipment cool while the front and/or back doors of the cabinet are opened for servicing.

### SUMMARY

According to one aspect of one or more embodiments of the present invention, a system comprises: electronic equipment; a device arranged to cool air using at least one of water and a refrigerant, where the device is secured to one of a right side and a left side of the electronic equipment; and a housing arranged to enclose the electronic equipment and the device, where the cooled air is propagated from one of the right side and the left side of the electronic equipment to the other one of the right side and the left side of the electronic equipment.

According to another aspect of one or more embodiments of the present invention, a method of cooling electronic equipment comprises: directing air heated by the electronic equipment to one of a right side and a left side of the electronic equipment; supplying one of water and a refrigerant to a device secured to the electronic equipment; generating cold air by using the device to cool the heated air; and directing the cold air into the other of the right side and the left side of the electronic equipment.

According to another aspect of one or more embodiments of the present invention, an apparatus comprises: electronic equipment; a heat exchanger secured to one of a right side and a left side of the electronic equipment, where the heat exchanger is arranged to cool air entering the heat exchanger; and a cabinet arranged to house the electronic equipment and the heat exchanger, where cold air generated by the heat exchanger is arranged to flow within the cabinet from one of the right side and the left side of the electronic equipment to the other one of the right side and the left side of the electronic equipment.

Other aspects and advantages of the invention will be apparent from the following description and the appended claims.

### BRIEF DESCRIPTION OF DRAWINGS

FIG. 1 shows a typical server room.

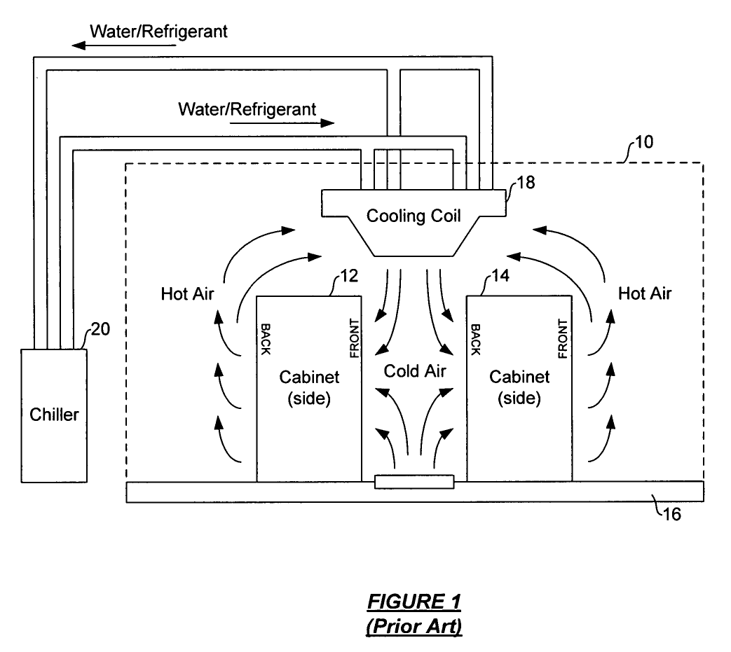

FIG. 2 shows a typical technique for cooling electronic equipment.

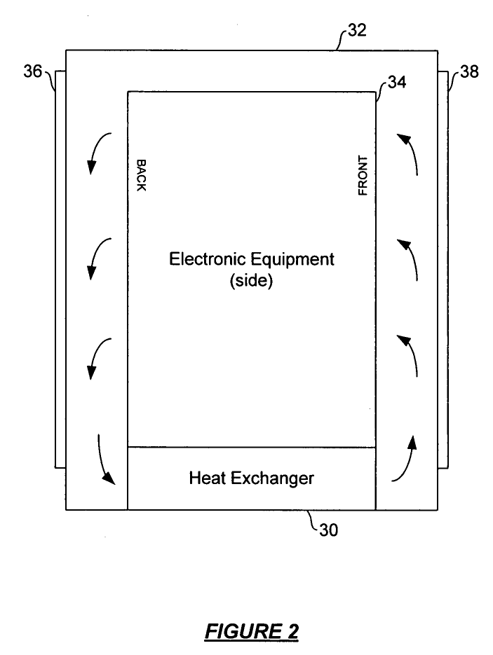

FIG. 3 shows a cooling technique in accordance with an embodiment of the present invention.

FIG. 4 shows a cooling technique in accordance with an embodiment of the present invention.

FIG. 5 shows a cooling technique in accordance with an embodiment of the present invention.

FIG. 6 shows a cooling technique in accordance with an embodiment of the present invention.

FIG. 7 shows a server room in accordance with an embodiment of the present invention.

### DETAILED DESCRIPTION

Embodiments of the present invention relate to a technique for cooling electronic equipment. In one or more embodiments of the present invention, electronic equipment is cooled by air that flows from/to a right side of the electronic equipment to/from a left side of the electronic equipment, where the air is cooled by an air-liquid heat exchanger secured to one of a right side and a left side of the electronic equipment.

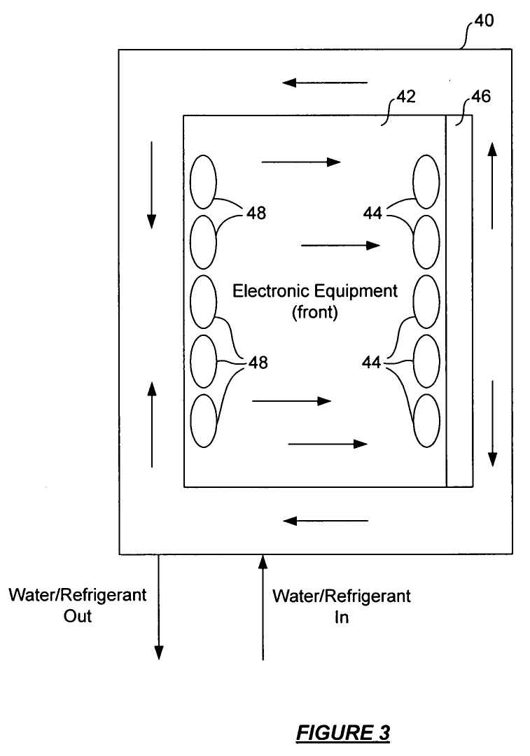

FIG. 3 shows an exemplary system in accordance with an embodiment of the present invention. Particularly, FIG. 3 shows a cross-sectional front view of a cabinet 40. The cabinet 40 houses electronic equipment 42. Air heated by heat dissipation from the electronic equipment 42 is directed by fans 44 (or other blowing devices) to an air-liquid heat exchanger 46 secured to a right side of the electronic equipment 42. The air-liquid heat exchanger 46 uses cold water/refrigerant supplied to the cabinet 40 to cool the hot air directed to the air-liquid heat exchanger 46. This process results in (i) heating the entering water/refrigerant, where the resulting warm water/refrigerant is directed away from the cabinet 40 and (ii) returning cold air to within the cabinet 40. The resulting cold air flows back around to a left side of the electronic equipment 42. Fans 48 (or other blowing devices) direct this cold air into the left side of the electronic equipment 42.

A refrigerant used in one or more embodiments of the present invention may be a liquid, a gas, or a gas-liquid (e.g., steam-water) two-phase fluid. For example, a refrigerant may be any one of air, ammonia, water, water vapor, carbon dioxide, or R134a.

As shown in FIG. 3, a technique for cooling electronic equipment in an embodiment of the present invention involves the flow of air from a left side of the electronic equipment to a right side of the electronic equipment. Those skilled in the art will note that in such an embodiment, the front and back sides of the electronic equipment are accessible without disrupting air flow in components of the electronic equipment not being accessed.

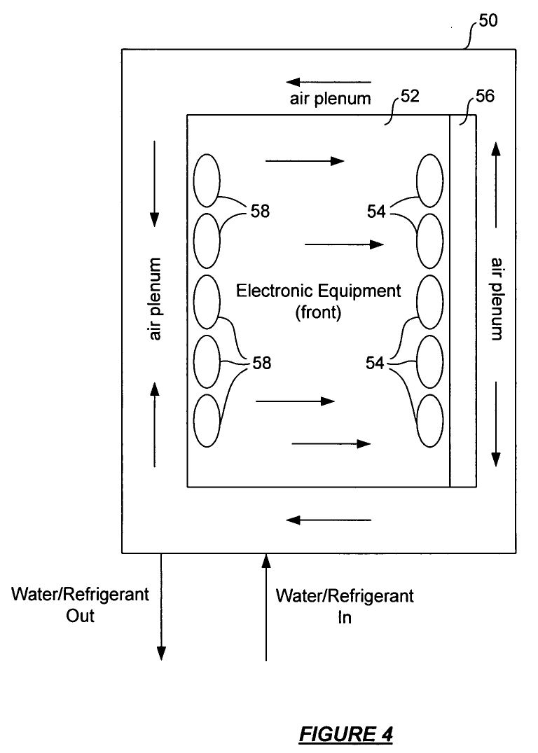

In one or more embodiments of the present invention, an air plenum may be implemented along an inside of the right and left sides and/or the top or bottom sides of a cabinet. For example, FIG. 4 shows such an exemplary system. Particularly, FIG. 4 shows a cross-sectional front view of a cabinet 50. The cabinet 50 houses electronic equipment 52. Air heated by heat dissipation from the electronic equipment 52 is directed by fans 54 (or other blowing devices) to an air-liquid heat exchanger 56 secured to a right side of the electronic equipment 52. The air-liquid heat exchanger 56 uses cold water/refrigerant supplied to the cabinet 50 to cool the hot air directed to the air-liquid heat exchanger 56. This process results in (i) heating the entering water/refrigerant, where the resulting warm water/refrigerant is directed away from the cabinet 50 and (ii) returning cold air being captured in an air plenum implemented along a right side of the cabinet 50. The resulting cold air flows back around (via an air plenum along a top side of the cabinet 50) to an air plenum implemented along a left side of the cabinet 50. Fans 58 (or other blowing devices) direct the cold air captured in the air plenum implemented along the left side of the cabinet 50 into the left side of electronic equipment 52.

In one or more embodiments of the present invention, instead of air flow from a left side of electronic equipment to a right side of the electronic equipment as shown in FIGS. 3 and 4, side-to-side air cooling may be achieved using air flow from a right side of electronic equipment to a left side of the electronic equipment.

Further, in one or more embodiments of the present invention, an air-liquid heat exchanger may be secured to a side of electronic equipment at which cold air enters the electronic equipment (instead of a side of the electronic equipment at which hot air exits as shown in FIGS. 3 and 4).

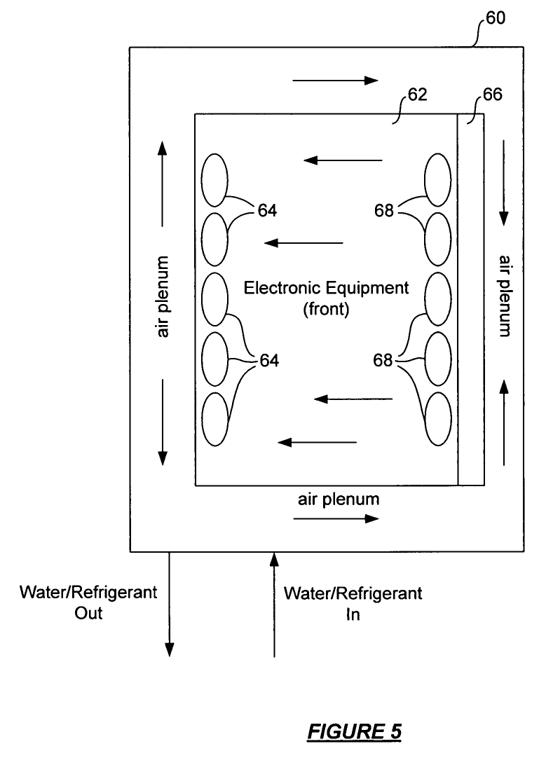

FIG. 5 shows such an exemplary system in accordance with an embodiment of the present invention. Particularly, FIG. 5 shows a cross-sectional front view of a cabinet 60. The cabinet 60 houses electronic equipment 62. Air heated by heat dissipation from the electronic equipment 62 is directed by fans 64 (or other blowing devices) to an air plenum implemented along a left side of the cabinet 60. The hot air flows back around (via an air plenum along a bottom side of the cabinet 60) to an air plenum implemented along a right side of the cabinet 60. The hot air in the air plenum implemented along the right side of the cabinet 60 enters an air-liquid heat exchanger 66 secured to a right side of the electronic equipment 62. The air-liquid heat exchanger 66 uses cold water/refrigerant supplied to the cabinet 60 to cool the hot air directed to the air-liquid heat exchanger 66. This process results in (i) heating the entering water/refrigerant, where the resulting warm water/refrigerant is directed away from the cabinet 60 and (ii) outputting cold air to fans 68 (or other blowing devices) that direct the cold air into the right side of electronic equipment 62.

In one or more embodiments of the present invention, a second air-liquid heat exchanger may be used. For example, with reference to FIG. 5, an air-liquid heat exchanger may be secured to a left side of the electronic equipment 62. Such an air-liquid heat exchanger would cool hot air from the electronic equipment 62 and return cold air to the air plenum implemented along the left side of the cabinet 60.

In one or more embodiments of the present invention, lines for water or a refrigerant may be directly connected to a component of electronic equipment housed in a cabinet. For example, a processor of a server component of electronic equipment housed in a cabinet may be connected water/refrigerant in/out lines so as to enable liquid cooling of the processor within the cabinet. Such an arrangement may be used for high heat dissipating elements, e.g., processors.

In one or more embodiments of the present invention, air flow through some components in electronic equipment may be from right-to-left, where air flow through other components in the electronic equipment may be from left-to-right. This may be achieved by, for example, creating particular air plenums to force the direction of air in the cabinet.

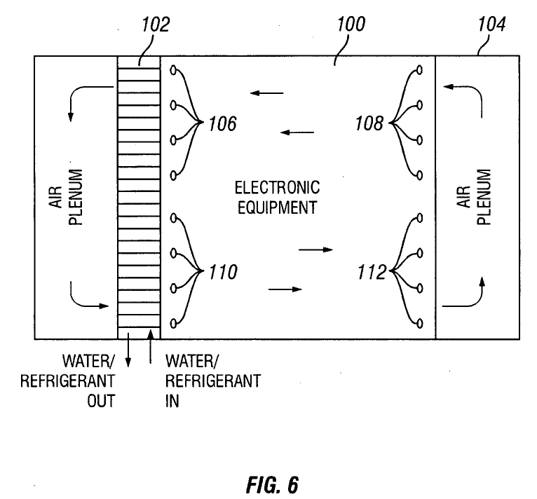

In one or more embodiments of the present invention, air may be re-circulated within a cabinet and through electronic equipment housed in the cabinet without passing air in front or behind the electronic equipment. For example, FIG. 6 shows such an exemplary system. Particularly, FIG. 6 shows a cross-sectional top view of a cabinet 104. Air heated via heat dissipation by electronic equipment 100 housed in a top portion of the cabinet 104 is directed by fans 106 (or other blowing devices) to an air-liquid heat exchanger 102. The air-liquid heat exchanger 102 cools the received hot air, where the resulting cold air is captured in an air plenum at the left side of the cabinet 104. The cold air in the air plenum at the left side of the cabinet 104 is directed by fans 110 (or other blowing devices) back through the air-liquid heat exchanger 102 to electronic equipment 100 housed in a bottom portion of the cabinet 104.

Air heated via heat dissipation by electronic equipment 100 housed in the bottom portion of the cabinet 104 is directed by fans 112 (or other blowing devices) to an air plenum at a right side of the cabinet 104. The air in the air plenum at the right side of the cabinet 104 is directed by fans 108 (or other blowing devices) to electronic equipment 100 housed in the top portion of the cabinet 104. Those skilled in the art will note that in such a manner, liquid-cooled air re-circulates from side to side of electronic equipment housed in the cabinet without passing in front of or behind the electronic equipment.

Further, in one or more embodiments of the present invention, electronic equipment housed in a cabinet may be segmented such that individual particular components of the electronic equipment have dedicated air plenums for the re-circulation of air.

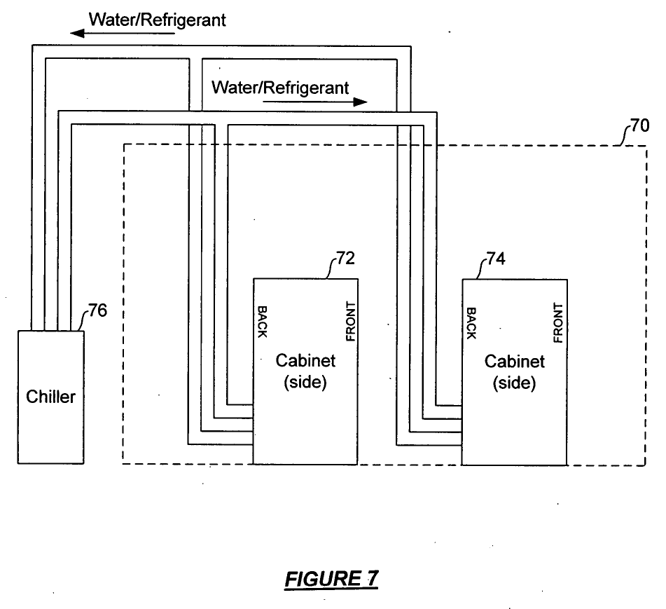

Those skilled in the art will note that in one or more embodiments of the present invention, a component in electronic equipment housed in a cabinet may be accessed without disrupting the cooling air flow of other components in the electronic equipment. As described above, in conventional front-to-back air flow cooling, a server room has to be equipped with adequate air conditioning so as to maintain cooling of even those components that are not being accessed when a front or back door of the cabinet is opened to access a particular component. Accordingly, in one or more embodiments of the present invention, separate air conditioning may not be required as components not being accessed remain air cooled by the same process occurring when the cabinet doors are closed. FIG. 6 shows an exemplary server room in accordance with an embodiment of the present invention. In FIG. 7, a server room 70 has two cabinets 72, 74. Each of the cabinets 72, 74 is connected to water/refrigerant lines (shown, but not labeled) that are connected to a chiller unit 76.

Further, in one or more embodiments of the present invention, if water or a refrigerant is not available in a particular server room, the electronic equipment may still be situated in the server room by removing the cabinet and any air-liquid heat exchangers. In such embodiments, air in the server room may flow from a right/left side of the electronic equipment to a left/right side of the electronic equipment using, for example, fans implemented with the electronic equipment and/or fans implemented within the server room. Alternatively, or perhaps in combination with side-to-side air flow, cooling air may flow, for example, in a front-to-back manner.

Advantages of the present invention may include one or more of the following. In one or more embodiments of the present invention, electronic equipment is air cooled using air that is cooled using a liquid-cooled cabinet.

In one or more embodiments of the present invention, the ability to air cool electronic equipment using liquid-cooled air may be used to cool electronic equipment having increased heat dissipation.

In one or more embodiments of the present invention, because electronic equipment is cooled from side-to-side instead of front-to-back, space on the front and rear of the electronic equipment that would otherwise be used to facilitate front-to-back air cooling (e.g., space need for air holes) may be instead used for connectors (e.g., power connections, input/output connections).

In one or more embodiments of the present invention, because air holes are not needed in a cabinet in which air contained within the cabinet flows from a right/left side to a left/right side of electronic equipment housed in the cabinet, electromagnetic interference may be better contained.

In one or more embodiments of the present invention, because electronic equipment is cooled from side-to-side instead of front-to-back, one or more components of the electronic equipment may be serviced/accessed without disrupting air flow in other components, thereby obviating the need for a separate air cooling mechanism to cool those other components were air flow directed from a front of the electronic equipment to a rear of the electronic equipment.

In one or more embodiments of the present invention, because electronic equipment is housed in a cabinet that uses air to cool the electronic equipment, where the air is contained within the cabinet, noise suppression of the electronic cabinet may be improved.

In one or more embodiments of the present invention, a cabinet is less dependent on an air flow rate or an air flow space of a server room than a cabinet which requires air flow in the server room to cool the electronic equipment in the cabinet either during normal operation or servicing.

In one or more embodiments of the present invention, because electronic equipment in a cabinet is cooled by cold air, there may be less of a risk of water or refrigerant leakage.

In one or more embodiments of the present invention, electronic equipment in a cabinet may be operated in a server room having only a power supply and a chiller unit (for communicating water/refrigerant with the cabinet).

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A system, comprising:
electronic equipment;
a device arranged to cool air using at least one of water and a refrigerant, the device secured to one of a right side and a left side of the electronic equipment; and
a housing arranged to enclose the electronic equipment and the device,
wherein the cooled air is propagated from one of the right side and the left side of the electronic equipment to the other one of the right side and the left side of the electronic equipment.

2. The system of claim 1, the electronic equipment comprising:
a plurality of computer systems; and
a chassis arranged to support the plurality of computer systems.

3. The system of claim 2, the plurality of computer systems comprising:
a server.

4. The system of claim 1, wherein the refrigerant is any one of air, ammonia, R134a, water vapor, and carbon dioxide.

5. The system of claim 1, the housing having a first door arranged to allow access to a front side of the electronic equipment.

6. The system of claim 1, the housing having a second door arranged to allow access to a rear side of the electronic equipment.

7. The system of claim 1, further comprising:
at least one blowing device implemented at one of the right side and the left side of the electronic equipment.

8. The system of claim 1, the housing comprising:
an air plenum implemented along a right side of the housing; and
an air plenum implemented along a left side of the housing.

9. The system of claim 8, the housing further comprising:
an air plenum implemented along any one or more of a bottom side and a top side of the housing.

10. The system of claim 1, further comprising:
a chiller unit operatively connected to the housing, the chiller unit arranged to supply the at least one of water and the refrigerant.

11. The system of claim 1, the electronic equipment comprising:
an element connected to a line arranged to propagate the at least one of the water and the refrigerant.

12. The system of claim 11, wherein the element is a processor.

13. A method of cooling electronic equipment, comprising:
directing air heated by the electronic equipment to one of a right side and a left side of the electronic equipment;
supplying one of water and a refrigerant to a device secured to the electronic equipment;
generating cold air by using the device to cool the heated air; and
directing the cold air into the other of the right side and the left side of the electronic equipment.

14. The method of claim 13, further comprising:
propagating air from one of the right side and the left side of the electronic equipment to the other of the right side and the left side of the electronic equipment.

15. The method of claim 13, wherein the refrigerant is any one of air, ammonia, water vapor, R134a, and carbon dioxide.

16. The method of claim 13, the electronic equipment being housed in a housing.

17. The method of claim 16, further comprising:
using an air plenum to direct one of the heated air and the cold air within the housing.

18. An apparatus, comprising:
electronic equipment;
a heat exchanger secured to one of a right side and a left side of the electronic equipment, the heat exchanger arranged to cool air entering the heat exchanger; and
a cabinet arranged to house the electronic equipment and the heat exchanger,
wherein cold air generated by the heat exchanger is arranged to flow within the cabinet from one of the right side and the left side of the electronic equipment to the other one of the right side and the left side of the electronic equipment.

19. The apparatus of claim 18, the electronic equipment comprising:
a plurality of servers; and
a rack arranged to support the plurality of servers.

20. The apparatus of claim 18, the cabinet comprising:
an air plenum implemented along a right side of the cabinet;
an air plenum implemented along a left side of the cabinet.

21. The apparatus of claim 18, wherein the heat exchanger is dependent on one of water and a refrigerant.

22. The apparatus of claim 18, wherein a front door of the cabinet is arranged to allow access to a front side of the electronic equipment.
